(19) United States
(12) Patent Application Publication
(10) Pub. No.: US 2025/0175092 A1
(43) Pub. Date: May 29, 2025

(54) ENERGY STORAGE INVERTER

(71) Applicant: Jinko Energy Storage Technology Co., Ltd., Haining (CN)

(72) Inventor: Jian YU, Haining (CN)

(21) Appl. No.: 18/731,406

(22) Filed: Jun. 3, 2024

(30) Foreign Application Priority Data
Nov. 24, 2023 (CN) 202311587167.8

(51) Int. Cl. H02M 7/00; H05K 7/20

(52) U.S. Cl. CPC H02M 7/003; H05K 7/20336; H05K 7/2089; H05K 7/20936

(57) ABSTRACT

An energy storage inverter, including: a substrate and at least one heat pipe set. The substrate is provided with an electronic element on one side and provided with a heat sink on the other side. The heat pipe set is arranged on one side of the heat sink close to the substrate and is connected to the heat sink. The heat pipe set includes at least one first heat pipe. The first heat pipe includes main body portion and extension portion. Along length direction of the main body portion, the extension portion is located on at least one side of the main body portion and is in communication with the main body portion. An angle is formed between the extension portion and the main body portion, and a ratio of a length of the main body portion to a length of the extension portion ranges from 4.3 to 4.5.

### CROSS-REFERENCE TO RELATED APPLICATION

The present application claims priority to Chinese Patent Application No. 202311587167.8, filed Nov. 24, 2023, the content of which is incorporated herein by reference in its entirety.

### TECHNICAL FIELD

The present disclosure relates to the technical field of energy storage and, in particular, to an energy storage inverter.

### BACKGROUND

With the development of science and technology, energy storage devices are more and more applied to different fields. The energy storage device is generally provided with an energy storage inverter. The energy storage inverter can realize conversion between direct current (DC) power and alternating current (AC) power, so that the energy storage device can supply power to the outside. The energy storage inverter is provided with a heat sink for heat dissipation. However, the conventional heat sink has poor heat dissipation effect, which easily affects normal operation of the energy storage inverter.

### SUMMARY

In view of this, the present disclosure provides an energy storage inverter to help solve the problem of poor heat dissipation effect of the heat sink of the energy storage inverter in the related art.

Embodiments of the present disclosure provide an energy storage inverter, including: a substrate provided with an electronic element on one side thereof and provided with a heat sink on the other side thereof; and at least one heat pipe set arranged on one side of the heat sink close to the substrate and connected to the heat sink. The heat pipe set includes at least one first heat pipe, the first heat pipe includes a main body portion and an extension portion, and along a length direction of the main body portion, the extension portion is located on at least one side of the main body portion and is in communication with the main body portion. An angle is formed between the extension portion and the main body portion, and a ratio of a length of the main body portion to a length of the extension portion ranges from 4.3 to 4.5.

In some embodiments, the first heat pipe includes one extension portion, along the length direction of the main body portion, the extension portion is located at one end of the main body portion, and the angle α between the main body portion and the extension portion ranges from 130° to 140°.

In some embodiments, the first heat pipe includes two extension portions. Along the length direction of the main body portion, the two extension portions are located at two ends of the main body portion, respectively. Along a width direction of the main body portion, the two extension portions extend towards a same side of the main body portion, or the two extension portions extend towards two sides of the main body portion.

In some embodiments, extension directions of the two extension portions are parallel to each other.

In some embodiments, the extension portion includes at least a first extension section and a second extension section, the second extension section is located on a side of the first extension section away from the main body portion and is in communication with the main body portion through the first extension section, and an angle is formed between the first extension section and the second extension section.

In some embodiments, the heat pipe set includes a plurality of first heat pipes. Along a length direction or a width direction of the heat sink, the plurality of first heat pipes are arranged at intervals, or the plurality of first heat pipes are arranged continuously.

In some embodiments, the heat pipe set further includes at least one second heat pipe, an extension direction of the second heat pipe is the same as an extension direction of the main body portion, and a length of the second heat pipe is less than a length of the first heat pipe.

In some embodiments, a ratio of the length of the second heat pipe to the length of the first heat pipe ranges from 0.81 to 0.84.

In some embodiments, in the heat pipe set, the first heat pipe and the second heat pipe are arranged along the length direction or the width direction of the heat sink, and the second heat pipe is located between two adjacent first heat pipes.

In some embodiments, in the heat pipe set, the first heat pipe and the second heat pipe are alternately arranged along the length direction or the width direction of the heat sink.

In some embodiments, the energy storage inverter includes a plurality of heat pipe sets. Along a length direction or a width direction of the heat sink, the plurality of heat pipe sets are arranged at intervals, or the plurality of heat pipe sets are arranged continuously.

In some embodiments, the heat sink includes a heat dissipation plate and a heat dissipation fin, the heat pipe set is arranged on the heat dissipation plate, and the heat dissipation fin is located on a side of the heat dissipation plate away from the heat pipe set and is connected to the heat dissipation plate.

### BRIEF DESCRIPTION OF DRAWINGS

In order to better illustrate the technical solutions in embodiments of the present disclosure, the accompanying drawings to be used in the description of the embodiments will be briefly introduced below. It is apparent that the accompanying drawings in the following description are only some embodiments of the present disclosure, and other drawings can be obtained by those of ordinary skill in the art from the provided drawings without creative efforts.

FIG. 1 is a schematic diagram of an energy storage inverter according to some embodiments of the present disclosure;

FIG. 2 is a schematic diagram of a heat sink according to some embodiments of the present disclosure;

FIG. 3 is a schematic diagram of a first heat pipe according to some embodiments of the present disclosure;

FIG. 4 is a schematic diagram of the first heat pipe according to some other embodiments of the present disclosure;

FIG. 5 is a schematic diagram of the first heat pipe according to some other embodiments of the present disclosure;

FIG. 6 is a schematic diagram of the first heat pipe according to some other embodiments of the present disclosure;

FIG. 7 is a schematic diagram of the first heat pipe according to some other embodiments of the present disclosure;

FIG. 8 is a front view of the heat sink according to some embodiments of the present disclosure; and

FIG. 9 is a front view of the heat sink according to some other embodiments of the present disclosure.

### DESCRIPTION OF EMBODIMENTS

In order to better understand the technical solution of the present disclosure, the embodiments of the present disclosure will be described in detail below with reference to the accompanying drawings.

It should be noted that the described embodiments are only some of, rather than all of the embodiments of the present disclosure. Based on the embodiments in the present disclosure, all other embodiments obtained by those of ordinary skill in the art without making creative efforts shall fall within the protection scope of the present disclosure.

The terms used in the embodiments of the present disclosure are for the purpose of describing embodiments only and are not intended to limit the present disclosure. As used in the embodiments of the present disclosure and the appended claims, the singular forms “a,” “an”, and “the” are intended to include the plural forms as well, unless the context clearly dictates otherwise.

It should be understood that the term “and/or” used herein is merely an association relationship describing associated objects, indicating that there may be three relationships. For example, A and/or B may indicate that there are three cases of A alone, A and B together, and B alone. In addition, the character “/” herein generally indicates that the related objects before and after the character form an “or” relationship.

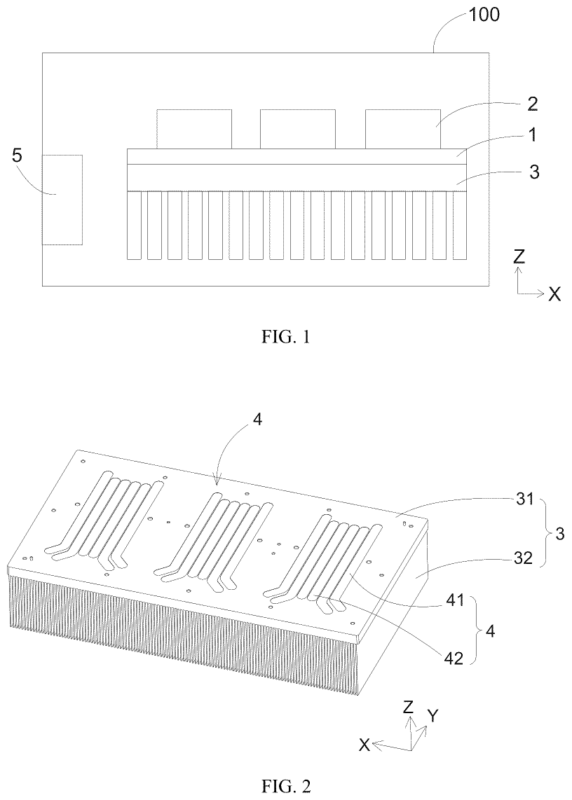

As shown in FIG. 1 to FIG. 3, some embodiments of the present disclosure provide an energy storage inverter 100, including: a substrate 1 and at least one heat pipe set 4. The substrate 1 is provided with an electronic element 2 on one side and provided with a heat sink 3 on the other side. The heat pipe set 4 is arranged on a side of the heat sink 3 close to the substrate 1 and is connected to the heat sink 3. The heat pipe set 4 includes at least one first heat pipe 41. The first heat pipe 41 includes a main body portion 411 and an extension portion 412. Along a length direction of the main body portion 411, the extension portion 412 is located on at least one side of the main body portion 411 and is in communication with the main body portion 411. An angle α is formed between the extension portion 412 and the main body portion 411, and a ratio of a length of the main body portion 411 to a length of the extension portion 412 ranges from 4.3 to 4.5.

During operation of the energy storage inverter 100, the electronic element 2 may dissipate a large amount of heat. The heat may be transferred to the substrate 1. The substrate 1 then transfers the heat to the heat sink 3 through the first heat pipe 41, so that thermal energy is dissipated through the heat sink 3. The substrate 1 may be a copper substrate. The copper substrate 1 has good thermal conductivity. The substrate 1 may be connected to the heat sink 3 through a fastener such as a screw (not shown in the figure), and the first heat pipe 41 may be embedded in the heat sink 3. The first heat pipe 41 has good thermal conductivity, which can realize rapid conduction of heat, so that the heat transferred from the substrate 1 can be quickly transferred to the heat sink 3, thereby helping to improve the heat dissipation effect of the heat sink 3. The heat pipe set 4 may be provided with a plurality of first heat pipes 41. In some embodiments, a length direction of the main body portion 411 of the first heat pipe 41 may be parallel to a width direction Y of the heat sink 3, and a width direction of the main body portion 411 may be parallel to a length direction X of the heat sink 3. The extension portion 412 is in communication with the main body portion 411, and is arranged obliquely relative to the main body portion 411. That is, extension directions of the main body portion 411 and the extension portion 412 are different. In some embodiments, the angle α between the extension portion 412 and the main body portion 411 may approximately range from 120° to 150°. Therefore, the main body portion 411 and the extension portion 412 may conduct heat towards different directions, thereby helping to increase the heat conduction capacity of the first heat pipe 41. In addition, the main body portion 411 and the extension portion 412 have different lengths, and the length of the main body portion 411 is greater than the length of the extension portion 412. It is to be noted that the length of the main body portion 411 is a dimension of the main body portion 411 in an extension direction thereof. Similarly, the length of the extension portion 412 is a dimension of the extension portion 412 in an extension direction thereof. For example, the ratio of the length of the main body portion 411 to the length of the extension portion 412 is 4.3, 4.33, 4.35, 4.37, 4.4, 4.43, 4.45, 4.47, or 4.5, and may be other values in the above range.

This design can effectively increase the heat conduction area of the first heat pipe, which is conducive to improving heat conduction efficiency of the first heat pipe, thereby helping to improve heat dissipation efficiency of the heat sink. Since an angle is formed between the main body portion and the extension portion, this enables the first heat pipe to conduct heat in different directions, so that the heat can be more evenly distributed to the heat sink to improve temperature uniformity of the heat sink, which further improves the heat dissipation effect of the heat sink, thereby improving heat dissipation performance of the energy storage inverter.

In some embodiments of the present disclosure, the first heat pipe 41 can quickly conduct heat, and by providing the first heat pipe 41 on the heat sink 3 or in the heat sink 3, heat emitted by the electronic element 2 can be quickly and effectively transferred to the heat sink 3. This heat dissipation manner has high reliability, so that the heat can be dissipated through the heat sink 3 in a timely manner, which reduces the possibility of malfunctioning of the electronic element 2 due to an excessive temperature, thereby helping to maintain normal operation of the energy storage inverter 100. For the first heat pipe 41, in the related art, the heat pipe on the heat sink generally has a small heat conduction area and low heat conduction efficiency, which adversely affects heat dissipation performance of the heat sink, thereby affecting normal operation of the entire energy storage inverter. In some embodiments of the present disclosure, the first heat pipe 41 has a main body portion 411 and an extension portion 412, and through the arrangement of the extension portion 412, the heat conduction area of the first heat pipe 41 can be effectively increased, which is conducive to improving heat conduction efficiency of the first heat pipe 41, thereby helping to improve heat dissipation performance of the heat sink 3. In addition, an angle is formed between the main body portion 411 and the extension portion 412, so that the first heat pipe 41 can conduct heat in different directions, which increases the heat conduction capacity of the first heat pipe 41 and allows the heat to be more evenly distributed to the heat sink 3, which is conducive to improving temperature uniformity of the heat sink 3, thereby helping further improve the heat dissipation effect of the heat sink 3. Based on the above, through the arrangement of the above first heat pipe 41, the heat sink 3 can have reliable heat dissipation performance, and it is also conducive to improving heat dissipation efficiency of the heat sink 3, thereby reducing the possibility of high-temperature failure of the electronic element 2, so that the energy storage inverter 100 can operate normally and stably. As a result, reliability of the entire energy storage inverter 100 can be improved.

As shown in FIG. 1, a fan 5 may also be provided inside the energy storage inverter 100. The operation of the fan 5 is conducive to further improving the heat dissipation effect of the heat sink 3, thereby improving overall heat dissipation performance of the energy storage inverter 100, so as to achieve normal and stable operation of the energy storage inverter 100.

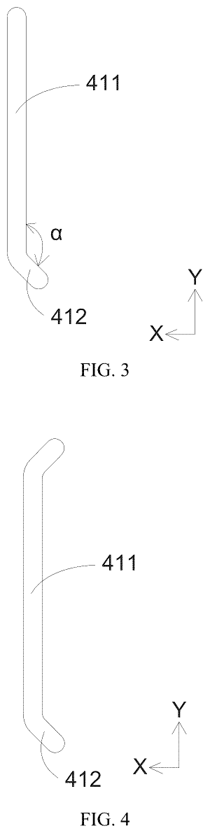

As shown in FIG. 3, in some embodiments, the first heat pipe 41 includes one extension portion 412, along a length direction of the main body portion 411, the extension portion 412 is located at one end of the main body portion 411, and an angle α between the main body portion 411 and the extension portion 412 ranges from 130° to 140°.

Along the length direction of the main body portion 411, the extension portion 412 may be arranged at an upper end of the main body portion 411 or at a lower end of the main body portion 411. The angle α between the main body portion 411 and the extension portion 412 may be 131°, 132°, 133°, 134°, 135°, 136°, 137°, 138°, 139°, or 140°, and may be other values in the above range. For example, the angle α may be 135°.

By limiting the angle range of the angle between the main body portion 411 and the extension portion 412, it is conducive to improving structural stability of the first heat pipe 41, thereby helping to improve reliability of the first heat pipe 41 and helping to prolong the service life of the first heat pipe 41, so that the reliability of the heat sink 3 can be improved. In addition, this can also facilitate machining and production of the first heat pipe 41.

In the above embodiments, the extension portion 412 is arranged at an end portion of the main body portion 411. In some other embodiments, the extension portion may alternatively be arranged at another position of the main body portion, such as at a midpoint of the main body portion. The position of the extension portion 412 may be correspondingly designed according to an actual position of a heat source (such as the position of the electronic element 2) in the energy storage inverter 100, to improve the heat dissipation effect of the heat sink 3.

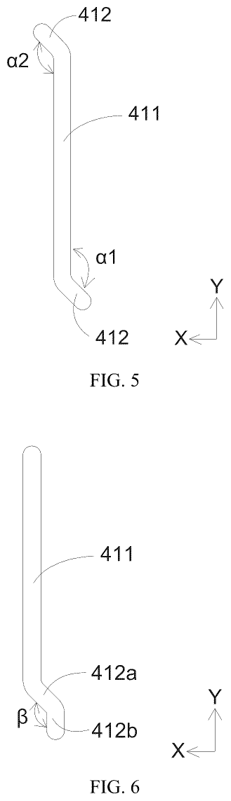

As shown in FIG. 4 and FIG. 5, in some embodiments, the first heat pipe 41 includes two extension portions 412, and along the length direction of the main body portion 411, the two extension portions 412 are located at two ends of the main body portion 411, respectively. Along the width direction of the main body portion 411, the two extension portions 412 extend towards a same side of the main body portion 411. Alternatively, the two extension portions 412 extend towards two sides of the main body portion 411.

Along the length direction of the main body portion 411, the two extension portions 412 may be arranged at an upper end and a lower end of the main body portion 411, respectively. Along the width direction of the main body portion 411, the two extension portions 412 may extend towards a same side of the main body portion 411, so that the first heat pipe 41 presents an approximately “C”-shaped structure. Alternatively, along the width direction of the main body portion 411, the two extension portions 412 extend towards two side of the main body portion 411 respectively, that is, extension directions of the two extension portions 412 are opposite, so that the first heat pipe 41 presents an approximately “Z”-shaped structure.

Through the arrangement of the two extension portions 412, it is conducive to further increasing the heat conduction area of the first heat pipe 41, thereby helping to improve heat conduction efficiency of the first heat pipe 41, so as to improve reliability of the first heat pipe 41. Moreover, this design also enables the heat to be more evenly distributed to the heat sink 3, which helps to improve temperature uniformity of the heat sink 3, thereby helping to improve the heat dissipation effect of the heat sink 3. The extension directions of the two extension portions 412 may be determined according to an actual position of the heat source, so as to improve the heat dissipation effect of the heat sink 3.

As shown in FIG. 5, in some embodiments, extension directions of the two extension portions 412 are parallel to each other.

In the two extension portions 412, an angle between one extension portion 412 and the main body portion 411 is al, and an angle between the other extension portion 412 and the main body portion 411 is α2. The angle α1 is the same as the angle α2. That is, the two extension portions 412 may be arranged in parallel. This design is conducive to improving the structural stability of the first heat pipe 41, thereby helping to prolong the service life of the first heat pipe 41. On the other hand, when the heat pipe set 4 includes a plurality of first heat pipes 41, the above design also helps realize parallel arrangement of the plurality of first heat pipes 41, to further improve the heat conduction effect of the heat pipe set 4.

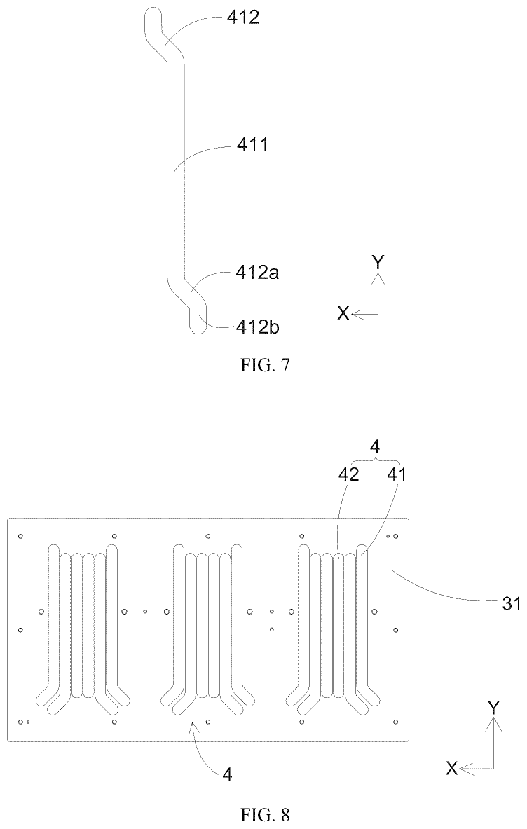

As shown in FIG. 6 and FIG. 7, in some embodiments, the extension portion 412 includes at least a first extension section 412a and a second extension section 412b. The second extension section 412b is located on a side of the first extension section 412a away from the main body portion 411 and is in communication with the main body portion 411 through the first extension section 412a. An angle β is formed between the first extension section 412a and the second extension section 412b.

The first extension section 412a and the second extension section 412b are connected to each other to form a bent structure. Lengths of the first extension section 412a and the second extension section 412b may be the same or different. Extension directions of the first extension section 412a and the second extension section 412b are different. In some embodiments, the main body portion 411, the first extension section 412a, and the second extension section 412b may all extend in different directions. Alternatively, the main body portion 411 may extend in a same direction as the second extension section 412b. The first extension section 412a has one end in communication with the main body portion 411 and the other end in communication with the second extension section 412b, and forms corresponding angles with the main body portion 411 and the second extension section 412b.

This design is conducive to further increasing the heat conduction area of the first heat pipe 41, and meanwhile, this also enables the first heat pipe 41 to conduct heat towards multiple directions, which further improves the heat conduction effect of the first heat pipe 41, thereby helping to improve the heat dissipation effect of the heat sink 3.

In some embodiments, the heat pipe set 4 includes a plurality of first heat pipes 41, and along a length direction X or a width direction Y of the heat sink 3, the plurality of first heat pipes 41 are arranged at intervals, or the plurality of first heat pipes 41 are arranged continuously.

The number, the arrangement direction, and the arrangement manner of the first heat pipes 41 may be designed accordingly according to an actual situation of the heat source and a distribution position thereof. In some embodiments, in the heat pipe set 4, the plurality of first heat pipes 41 may be evenly arranged at intervals, or the plurality of first heat pipes 41 may be unevenly arranged at intervals. For example, a spacing distance between adjacent first heat pipes 41 gradually increases or decreases towards an edge of the heat sink 3. It is appreciated that, the plurality of first heat pipes 41 may be arranged continuously. In some other embodiments, one part of the first heat pipes 41 in the heat pipe set 4 may be arranged at intervals, and the other part may be arranged continuously.

The heat sink 3 may be provided with a plurality of heat pipe sets 4. Numbers of the first heat pipes 41 in the heat pipe sets 4 may be the same or different. The first heat pipes 41 in one part of the heat pipe sets 4 may be arranged along the length direction X of the heat sink 3, and the first heat pipes 41 in the other part of the heat pipe sets 4 may be arranged along the width direction Y of the heat sink 3. In addition, the first heat pipes 41 in one part of the heat pipe sets 4 may be arranged at intervals, and the first heat pipes 41 in the other part of the heat pipe sets 4 may be arranged continuously.

By designing the arrangement manner of the first heat pipes 41, the heat pipe set 4 can better adapt to the heat source, which helps to improve an overall heat conduction effect of the heat pipe set 4, thereby helping to improve the heat dissipation effect of the heat sink 3 and helping to improve heat dissipation efficiency thereof, so as to realize stable and normal operation of the energy storage inverter 100.

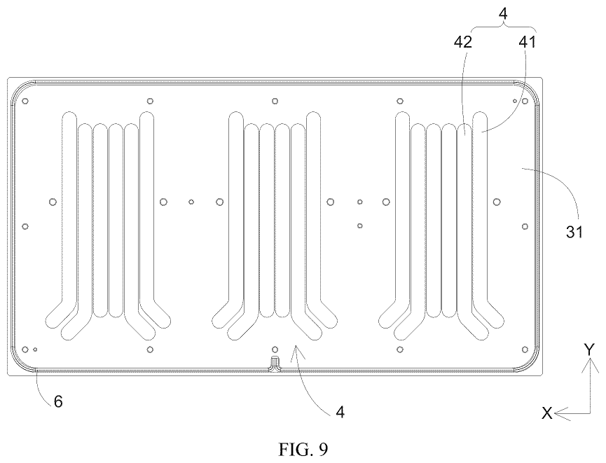

As shown in FIG. 2 and FIG. 8, in some embodiments, the heat pipe set 4 further includes at least one second heat pipe 42, an extension direction of the second heat pipe 42 is the same as an extension direction of the main body portion 411, and a length of the second heat pipe 42 is less than a length of the first heat pipe 41.

The heat pipe set 4 is provided with the first heat pipe 41 and the second heat pipe 42 at the same time. Similarly, the second heat pipe 42 can also achieve rapid heat conduction. In the heat pipe set 4, one or more second heat pipes 42 may be provided, and the length of the second heat pipe 42 may be the same as the length of the main body portion 411 in the first heat pipe 41. Since the first heat pipe 41 further includes the extension portion 412, the length of the second heat pipe 42 is less than the length of the first heat pipe 41.

The second heat pipe 42 has a lower production cost due to a smaller size. The second heat pipe 42 is conducive to reducing cost of the heat pipe set 4 while ensuring the overall heat conduction effect of the heat pipe set 4, thereby helping to reduce the production cost of the entire energy storage inverter 100. On the other hand, the heat pipe set 4 is provided with two types of heat pipes with different sizes and specifications. This design is conducive to improving overall reliability of the heat pipe set 4, allowing the heat pipe set 4 to better adapt to the heat source, thereby helping to improve the heat dissipation effect of the heat sink 3.

In some embodiments, a ratio of the length of the second heat pipe 42 to the length of the first heat pipe 41 ranges from 0.81 to 0.84.

For example, the ratio of the length of the second heat pipe 42 to the length of the first heat pipe 41 is 0.81, 0.82, 0.83, or 0.84, and may be other values in the above range. By further limiting the length of the second heat pipe 42, it is conducive to improving a heat conduction effect of the second heat pipe 42, thereby helping to improve the heat conduction effect of the entire heat pipe set 4 and also helping to reduce the overall use cost of the heat pipe set 4.

As shown in FIG. 8, in some embodiments, in the heat pipe set 4, the first heat pipe 41 and the second heat pipe 42 are arranged along the length direction X or the width direction Y of the heat sink 3. The second heat pipe 42 is located between two adjacent first heat pipes 41.

A plurality of second heat pipes 42 may be provided. In some embodiments, the plurality of second heat pipes 42 are provided between two adjacent first heat pipes 41, and the plurality of second heat pipes 42 may be arranged continuously or arranged at intervals. For example, the heat pipe set 4 may include four first heat pipes 41 and two second heat pipes 42, and the four first heat pipes 41 are respectively arranged in pairs on two sides of the two second heat pipes 42, so that the heat pipe set 4 has a symmetrical structure.

By designing the arrangement manners of the first heat pipe 41 and the second heat pipe 42, the heat pipe set 4 as an entirety can better adapt to the heat source, thereby helping to improve the overall heat conduction effect of the heat pipe set 4 and helping to improve the heat dissipation effect of the heat sink 3.

In some embodiments, in the heat pipe set 4, the first heat pipe 41 and the second heat pipe 42 are alternately arranged along the length direction X or the width direction Y of the heat sink 3.

A plurality of first heat pipes 41 and a plurality of second heat pipes 42 may be provided in the heat pipe set 4, and are alternately arranged. Adjacent first heat pipes 41 and second heat pipes 42 may be arranged at intervals or continuously.

This design is conducive to achieving even arrangement of the first heat pipe 41 and the second heat pipe 42 on the heat sink 3, thereby helping to improve the overall heat conduction effect of the heat pipe set 4 to improve reliability of the heat pipe set 4, so that the heat can be efficiently and evenly transferred to the heat sink 3 through the heat pipe set 4, which is conducive to improving the heat dissipation effect and the heat dissipation efficiency of the heat sink 3.

As shown in FIG. 8, in some embodiments, the energy storage inverter 100 includes a plurality of heat pipe sets 4, and along the length direction X or the width direction Y of the heat sink 3, the plurality of heat pipe sets 4 are arranged at intervals, or the plurality of heat pipe sets 4 are arranged continuously.

Two, three, four, or more heat pipe sets 4 may be provided. The plurality of heat pipe sets 4 may be arranged along the length direction X of the heat sink 3, or arranged along the width direction Y of the heat sink 3. The plurality of heat pipe sets 4 may be arranged at intervals. In some embodiments, a spacing distance between adjacent heat pipe sets 4 may be determined according to position distribution of the heat source. It is appreciated that, the plurality of heat pipe sets 4 may alternatively be arranged continuously.

Through the arrangement of the plurality of heat pipe sets 4, the heat conduction area is further increased, and the heat can be more evenly transferred to a heat dissipation plate 31, which is conducive to further improving the heat dissipation effect of the heat sink 3, thereby helping to achieve normal and stable operation of the energy storage inverter 100.

As shown in FIG. 2 and FIG. 8, in some embodiments, the heat sink 3 includes a heat dissipation plate 31 and a heat dissipation fin 32, the heat pipe set 4 is arranged on the heat dissipation plate 31, and the heat dissipation fin 32 is located on a side of the heat dissipation plate 31 away from the heat pipe set 4 and is connected to the heat dissipation plate 31.

The heat dissipation plate 31 may abut against the substrate 1. The heat pipes in the heat pipe set 4 are embedded in the heat dissipation plate 31. The other side of the heat dissipation plate 31 is fixedly connected to a plurality of heat dissipation fins 32. Two adjacent heat dissipation fins 32 are arranged at intervals. The heat dissipation fin 32 can fully contact the air, thereby dissipating the heat into the air more quickly and effectively. Therefore, through the arrangement of the heat dissipation fin 32, it is conducive to further improving the overall heat dissipation efficiency of the heat sink 3, so as to improve reliability of the heat sink 3.

As shown in FIG. 9, in some other embodiments, a sealing strip 6 may be provided on the heat dissipation plate 31. Referring to FIG. 1, when the substrate 1 is connected to the heat sink 3, the sealing strip 6 can abut against the substrate 1, thereby achieving a sealed connection between the substrate 1 and the heat sink 3 to improve sealing performance between the heat sink 3 and the substrate 1, and improving the heat dissipation effect of the heat sink 3. The heat dissipation plate 31 may be provided with a mounting groove (not shown in the figure). The sealing strip 6 may be mounted in the mounting groove, and two ends of the sealing strip 6 may be clamped in the mounting groove, so that the sealing strip 6 is connected end to end to form a closed annular structure. The heat pipe set 4 is located in the annular structure. That is, the sealing strip 6 can enclose each heat pipe set 4, and a certain distance is reserved between the sealing strip 6 and the heat pipe set 4. This design reduces the possibility of interference between the sealing strip 6 and the heat pipe set 4, and facilitates assembly of the two with the heat dissipation plate 31. Moreover, the possibility that the heat pipe set 4 transfers the heat to the sealing strip 6, causing the sealing strip 6 to fail to operate normally due to a rising temperature is reduced, thereby helping to prolong the service life of the sealing strip 6.

The above embodiments are merely preferred embodiments of the present disclosure and are not intended to limit the present disclosure. Various changes and modifications can be made to the present disclosure by those skilled in the art. Any modifications, equivalent substitutions and improvements made within the spirit and principle of the present disclosure shall fall into the protection scope of the present disclosure.

What is claimed is:

1. An energy storage inverter, comprising:
a substrate provided with an electronic element on one side thereof and provided with a heat sink on the other side thereof; and
at least one heat pipe set arranged on one side of the heat sink close to the substrate and connected to the heat sink,
wherein the heat pipe set comprises at least one first heat pipe, the first heat pipe comprises a main body portion and an extension portion, and along a length direction of the main body portion, the extension portion is located on at least one side of the main body portion and is in communication with the main body portion; wherein an angle α is formed between the extension portion and the main body portion, and a ratio of a length of the main body portion to a length of the extension portion ranges from 4.3 to 4.5.

2. The energy storage inverter according to claim 1, wherein the first heat pipe comprises one extension portion, along the length direction of the main body portion, the extension portion is located at one end of the main body portion, and the angle α between the main body portion and the extension portion ranges from 130° to 140°.

3. The energy storage inverter according to claim 1, wherein the first heat pipe comprises one extension portion, along the length direction of the main body portion, the extension portion is located at a midpoint of the main body portion.

4. The energy storage inverter according to claim 1, wherein the first heat pipe comprises two extension portions;
along the length direction of the main body portion, the two extension portions are located at two ends of the main body portion, respectively; and
along a width direction of the main body portion, the two extension portions extend towards a same side of the main body portion.

5. The energy storage inverter according to claim 4, wherein the two extension portions extend towards a same side of the main body portion to form a C-shaped structure.

6. The energy storage inverter according to claim 1, wherein the first heat pipe comprises two extension portions;
along the length direction of the main body portion, the two extension portions are located at two ends of the main body portion, respectively; and
along a width direction of the main body portion, the two extension portions extend towards two sides of the main body portion.

7. The energy storage inverter according to claim 6, wherein the two extension portions extend towards two sides of the main body portion to form a Z-shaped structure.

8. The energy storage inverter according to claim 1, wherein the first heat pipe comprises two extension portions, and extension directions of the two extension portions are parallel to each other.

9. The energy storage inverter according to claim 1, wherein the extension portion comprises at least a first extension section and a second extension section, the second extension section is located on a side of the first extension section away from the main body portion and is in communication with the main body portion through the first extension section, and an angle β is formed between the first extension section and the second extension section.

10. The energy storage inverter according to claim 9, wherein the angle α equals to the angle β.

11. The energy storage inverter according to claim 9, wherein the angle α differs from the angle β.

12. The energy storage inverter according to claim 1, wherein the heat pipe set comprises a plurality of first heat pipes; and
along a length direction or a width direction of the heat sink, the plurality of first heat pipes are arranged at intervals.

13. The energy storage inverter according to claim 1, wherein the heat pipe set comprises a plurality of first heat pipes; and
along a length direction or a width direction of the heat sink, the plurality of first heat pipes are arranged continuously.

14. The energy storage inverter according to claim 1, wherein the heat pipe set further comprises at least one second heat pipe, an extension direction of the second heat pipe is the same as an extension direction of the main body portion, and a length of the second heat pipe is less than a length of the first heat pipe.

15. The energy storage inverter according to claim 14, wherein a ratio of the length of the second heat pipe to the length of the first heat pipe ranges from 0.81 to 0.84.

16. The energy storage inverter according to claim 14, wherein in the heat pipe set, the first heat pipe and the second heat pipe are arranged along the length direction or the width direction of the heat sink, and the second heat pipe is located between two adjacent first heat pipes.

17. The energy storage inverter according to claim 14, wherein in the heat pipe set, the first heat pipe and the second heat pipe are alternately arranged along the length direction or the width direction of the heat sink.

18. The energy storage inverter according to claim 14, wherein the energy storage inverter comprises a plurality of heat pipe sets; and
along the length direction or the width direction of the heat sink, the plurality of heat pipe sets are arranged at intervals.

19. The energy storage inverter according to claim 14, wherein the energy storage inverter comprises a plurality of heat pipe sets; and
along the length direction or the width direction of the heat sink, the plurality of heat pipe sets are arranged continuously.

20. The energy storage inverter according to claim 1, wherein the heat sink comprises a heat dissipation plate and a heat dissipation fin, the heat pipe set is arranged on the heat dissipation plate, and the heat dissipation fin is located on a side of the heat dissipation plate away from the heat pipe set and is connected to the heat dissipation plate.
